(19) United States
(12) Patent Application Publication
(10) Pub. No.: US 2022/0298381 A1
(43) Pub. Date: Sep. 22, 2022

(54) CMP SLURRY COMPOSITION FOR POLISHING TUNGSTEN PATTERN WAFER AND METHOD OF POLISHING TUNGSTEN PATTERN WAFER USING THE SAME

(71) Applicant: SAMSUNG SDI CO., LTD., Yongin-si (KR)

(72) Inventors: Soo Yeon SIM, Suwon-si (KR); Ji Ho LEE, Suwon-si (KR); Hyun Woo LEE, Suwon-si (KR); Jong Won LEE, Suwon-si (KR)

(21) Appl. No.: 17/695,006

(22) Filed: Mar. 15, 2022

(30) Foreign Application Priority Data
Mar. 18, 2021 (KR) 10-2021-0035577

(51) Int. Cl. C09G 1/04

(52) U.S. Cl. CPC C09G 1/04; H01L 21/304

(57) ABSTRACT

A CMP slurry composition for polishing a tungsten pattern wafer and a method of polishing a tungsten pattern wafer using the same. The CMP composition includes: a solvent; an abrasive agent; and a dendritic poly(amidoamine) containing a terminal amino group.

### CROSS-REFERENCE TO RELATED APPLICATION

This application claims priority, under 35 USC Section 119, to and the benefit of Korean Patent Application No. 10-2021-0035577, filed on Mar. 18, 2021, the entire disclosure of which is incorporated herein by reference.

### BACKGROUND

### 1. Field

Embodiments relate to a CMP slurry composition for polishing a tungsten pattern wafer and a method of polishing a tungsten pattern wafer using the same.

### 2. Description of the Related Art

A chemical mechanical polishing (CMP) composition and a method of polishing (or flattening) a surface of a substrate have been considered. A polishing composition for polishing a metal layer (e.g., a tungsten layer) on a semiconductor substrate may include abrasive particles suspended in an aqueous solution and chemical accelerators, e.g., an oxidizing agent, a catalyst, or the like.

A process of polishing a metal layer using the CMP composition may include polishing only the metal layer, polishing the metal layer and a barrier layer, and polishing the metal layer, the barrier layer, and an oxide layer.

### SUMMARY

The embodiments may be realized by providing a CMP slurry composition for polishing a tungsten pattern wafer, the composition including a solvent; an abrasive agent; and a dendritic poly(amidoamine) containing a terminal amino group.

The dendritic poly(amidoamine) may include poly(amidoamine) dendrimers.

The dendritic poly(amidoamine) may have a generation number of 1, 2, 3, 4, 5, 6, 7, 8, 9, or 10.

The dendritic poly(amidoamine) may have a generation number of 1, 2, 3, 4, or 5.

The terminal amino group may occupy about 10% to about 100% of total terminal groups of the dendritic poly(amidoamine).

The dendritic poly(amidoamine) may be present in an amount of about 0.0001 wt % to about 0.1 wt %, based on a total weight of the CMP slurry composition.

The abrasive agent may be present in an amount of about 0.001 wt % to about 20 wt %, based on a total weight of the CMP slurry composition.

The CMP slurry composition may further include an oxidizing agent, a catalyst, or an organic acid.

The oxidizing agent may be present in an amount of about 0.01 wt % to about 20 wt %, the catalyst may be present in an amount of about 0.001 wt % to about 10 wt %, and the organic acid may be present in an amount of about 0.001 wt % to about 10 wt %, based on a total weight of the CMP slurry composition.

The CMP slurry composition may have a pH of about 1 to about 6.

The embodiments may be realized by providing a method of polishing a tungsten pattern wafer, the method comprising polishing a tungsten pattern wafer using the CMP slurry composition according to an embodiment.

### DETAILED DESCRIPTION

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or substrate, or intervening layers may also be present. In addition, it will also be understood that when a layer is referred to as being “between” two layers, it can be the only layer between the two layers, or one or more intervening layers may also be present.

Herein, the singular forms “a”, “an” and “the” are intended to include the plural forms as well, unless the context clearly indicates otherwise.

Further, all variations of the terms “comprise,” “include,” “have,” etc., when used in this specification, specify the presence of stated features, steps, operations, elements, and/or components, but do not preclude the presence or addition of one or more other features, steps, operations, elements, components, and/or groups. As used herein, the term “or” is not an exclusive term, e.g., “A or B” would include A, B, or A and B.

Further, a numerical value related to a certain component is construed to include a tolerance range in interpretation of components, unless clearly stated otherwise.

As used herein to represent a specific numerical range, the expression “a to b” is inclusive of a and b.

Herein, * indicates a linking site between adjacent atoms.

A CMP slurry composition for polishing a tungsten pattern wafer according to an embodiment may help improve flatness of the tungsten pattern wafer while reducing a corrosion rate thereof, e.g., when an abrasive agent and a dendritic poly(amidoamine) containing a terminal amino group are included therein.

In accordance with an embodiment, a CMP slurry composition for polishing a tungsten pattern wafer (hereinafter referred to as “CMP slurry composition”) may include, e.g., (A) a solvent, (B) an abrasive agent, and (C) a dendritic poly(amidoamine) containing a terminal amino group.

Hereinafter, components of the CMP slurry composition will be described in detail.

(A) Solvent

The solvent may serve to reduce friction upon polishing a tungsten pattern wafer with an abrasive agent.

In an implementation, the solvent may be a polar solvent, a non-polar solvent, or a combination thereof. In an implementation, the solvent may include water (e.g., ultrapure water or deionized water), an organic amine, an organic alcohol, an organic alcohol amine, an organic ether, an organic ketone, or the like. In an implementation, the solvent may be ultrapure water or deionized water.

In an implementation, the solvent may be included in the balance amount in the CMP slurry composition.

(B) Abrasive Agent

The abrasive agent may serve to polish a tungsten pattern wafer at a high polishing rate.

In an implementation, the abrasive agent may include, e.g., oxide abrasive particles of a metal or non-metal. In an implementation, the abrasive agent may include silica, alumina, ceria, titania, or zirconia. In an implementation, the abrasive agent may be silica (e.g., colloidal silica).

In an implementation, the abrasive agent may be composed of spherical or aspherical particles and may have an average particle diameter (D50) of about 10 nm to about 200 nm, e.g., about 20 nm to about 180 nm, or about 30 nm to about 150 nm. Within this range, the agent abrasive may help polish the tungsten pattern wafer at a sufficiently high polishing rate. As used herein, the “average particle diameter (D50)” refers to a particle diameter corresponding to about 50 vol % in a volume distribution of abrasive particles distributed in the order of the minimum size to the maximum size.

In an implementation, the abrasive agent may be present in an amount of about 0.001 wt % to about 20 wt %, e.g., about 0.01 wt % to about 15 wt %, about 0.05 wt % to about 10 wt %, or about 0.1 wt % to about 8 wt %, based on a total weight of the CMP slurry composition. Within this range, the CMP slurry composition may help secure a high polishing rate with respect to the tungsten pattern wafer while securing dispersion stability of the slurry composition.

(C) Dendritic Poly(Amidoamine)

In an implementation, the dendritic poly(amidoamine) may contain or include a terminal amino group (—NH₂). The CMP polishing composition according to an embodiment may include the dendritic poly(amidoamine) containing a terminal amino group (—NH₂) (hereinafter, “dendritic poly(amidoamine)”) to help improve flatness of the tungsten pattern wafer while reducing a corrosion rate thereof.

The dendritic poly(amidoamine) may include, e.g., random hyperbranched poly(amidoamine), dendrigraft poly(amidoamine), poly(amidoamine) dendron, poly(amidoamine) dendrimer, or the like. In an implementation, the dendritic poly(amidoamine) may include poly(amidoamine) dendrimers, thereby providing more advantages in improvement of flatness of the tungsten pattern wafer while reducing the corrosion rate.

In an implementation, the dendritic poly(amidoamine) may be produced by sequentially reacting a carboxylic acid derivative compound (e.g., a carboxylic acid-containing compound) and a diamine compound with a core amine compound having at least one hydrogen bound to a nitrogen atom. In an implementation, the core amine compound may be represented by, e.g., Formula 1.

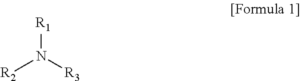

In Formula 1, R₁ to R₃ may each independently be or include, e.g., hydrogen or a C₁ to C₁₀ alkyl group. In an implementation, at least one of R₁ to R₃ may be hydrogen. In an implementation; R₁ may be a group represented by *-L₁-N(R₁ₐ)(R_{1b}) (in which L₁ is a single bond or a C₁ to C₁₀ alkylene group, and R₁ₐ and R_{1b} are each independently hydrogen or a C₁ to C₁₀ alkyl group) and R₂ and R₃ may each independently be hydrogen or a C₁ to C₁₀ alkyl group. In an implementation, at least one of R₁ₐ, R_{1b}, R₂ and R₃ may be hydrogen. In an implementation, R₁ may be a group represented by *-L₁-N(R₁ₐ)(R_{1b}), R₂ may be a group represented by *-L₂-N(R₂ₐ)(R_{2b}) (in which L₁ and L₂ are each independently a single bond or a C₁ to C₁₀ alkylene group, and R₁ₐ, R_{1b}, R₂ₐ and R_{2b} are each independently hydrogen or a C₁ to C₁₀ alkyl group), and R₃ may be hydrogen or a C₁ to C₁₀ alkyl group. In an implementation, at least one of R₁ₐ, R_{1b}, R₂ₐ, R_{2b} and R₃ may be hydrogen. In an implementation; R₁ may be a group represented by *-L₁-N(R₁ₐ)(R_{1b}), R₂ may be a group represented by *-L₂-N(R₂ₐ)(R_{2b}), and R₃ may be a group represented by *-L₃-N(R₃ₐ)(R_{3b}) (in which L₁ to L₃ are each independently a single bond or a C₁ to C₁₀ alkylene group, and R₁ₐ, R_{1b}, R₂ₐ, R_{2b}, R₃ₐ and R_{3b} are each independently hydrogen or a C₁ to C₁₀ alkyl group). In an implementation, at least one of R₁ₐ, R_{1b}, R₂ₐ, R_{2b}, R₃ₐ and R_{3b} may be hydrogen.

In an implementation, the core amine compound may include, e.g., ammonia (NH₃) or ethylene diamine. The carboxylic acid derivative compound may be represented by, e.g., CH₂CH-L₄-CO₂X (in which L₄ is a single bond or a C₁ to C₁₀ alkylene group and X is hydrogen, a cation, a C₁ to C₁₀ alkyl group, or a C₆ to C₁₂ aryl group) and the diamine compound may be represented by, e.g., H₂N-L₅-NH₂ (in which L₅ is a single bond or a C₁ to C₁₀ alkylene group). In an implementation, the dendritic poly(amidoamine) may have a repeat group of Formula 2 and a surface group of Formula 3.

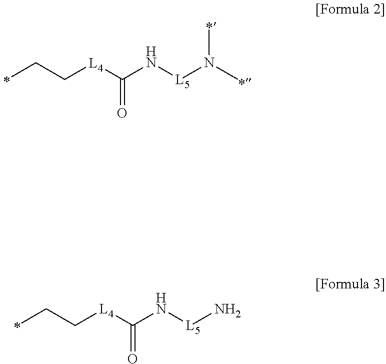

In Formulas 2 and 3, L₄ and L₅ may each independently be a single bond or a C₁ to C₁₀ alkylene group; and *, *′, and *″ denote linking sites to adjacent atoms.

In an implementation, the dendritic poly(amidoamine) may have a generation number of n (in which, n is an integer of 1 to 10). In an implementation, the dendritic poly(amidoamine) may have a generation number of 1, 2, 3, 4, 5, 6, 7, 8, 9, or 10. Within this range, the dendritic poly(amidoamine) may more advantageously improve flatness of the tungsten pattern wafer and corrosion rate thereof. Here, “generation number” refers to the number of branched points from a core of the dendritic poly(amidoamine) to a surface thereof and a generation n dendritic poly(amidoamine) may have n branched points between the core and the surface. The generation n dendritic poly(amidoamine) may be produced through n+1 times repeated sequential reaction of the carboxylic acid/diamine compound with the core. In an implementation, a generation 1 dendritic poly(amidoamine) may be produced through sequential reaction of the carboxylic acid/diamine compound/carboxylic acid/diamine compound with the core.

In an implementation, the dendritic poly(amidoamine) may have a generation number of 1, 2, 3, 4, or 5.

In an implementation, the terminal amino group may occupy about 10% to about 100% of total terminal groups of the dendritic poly(amidoamine). Within this range, the dendritic poly(amidoamine) may more advantageously improve flatness of the tungsten pattern wafer while reducing the corrosion rate. In an implementation, the terminal amino group may occupy about 20% to about 100%, e.g., about 30% to about 100%, or about 40% to about 100%, of the total terminal groups in the dendritic poly(amidoamine).

In an implementation, the dendritic poly(amidoamine) may be present in an amount of about 0.0001 wt % to about 0.1 wt %, e.g., about 0.001 wt % to about 0.02 wt %, or about 0.002 wt % to about 0.01 wt %, based on the total weight of the CMP slurry composition. Within this range, the dendritic poly(amidoamine) may more advantageously improve flatness of the tungsten pattern wafer while reducing the corrosion rate thereof.

In an implementation, the CMP slurry composition may further include, e.g., (D) an oxidizing agent, (E) a catalyst, or (F) an organic acid.

(D) Oxidizing Agent

The oxidizing agent may facilitate polishing of the tungsten pattern wafer by oxidizing the tungsten pattern wafer.

In an implementation, the oxidizing agent may include, e.g., an inorganic per compound, an organic per compound, bromic acid or salts thereof, nitric acid or salts thereof, chloric acid or salts thereof, chromic acid or salts thereof, iodic acid or salts thereof, iron or salts thereof, copper or salts thereof, rare-earth metal oxides, transition metal oxides, potassium dichromate, or mixtures thereof. Here, the per compound refers to a compound that contains at least one peroxide group (—O—O—) or an element in the highest oxidation state. In an implementation, the oxidizing agent may include a per compound (e.g., hydrogen peroxide, potassium periodide, calcium persulfate, potassium ferricyanide, or the like). In an implementation, the oxidizing agent may be hydrogen peroxide.

In an implementation, the oxidizing agent may be present in an amount of about 0.01 wt % to about 20 wt %, e.g., about 0.05 wt % to about 15 wt %, about 0.1 wt % to about 10 wt %, or about 0.5 wt % to about 8 wt %, based on a total weight of the CMP slurry composition. Within this range, the CMP slurry composition may help improve the polishing rate of the tungsten metal layer.

(E) Catalyst

The catalyst may help improve the polishing rate of the tungsten pattern wafer.

In an implementation, the catalyst may include, e.g., an iron ion compound, a complex compound of iron ions, or a hydrate thereof.

In an implementation, the iron ion compound may include, e.g., an iron trivalent cation-containing compound. The iron trivalent cation-containing compound may be a suitable compound having iron trivalent cations, which are present as free cations in an aqueous solution. In an implementation, the iron trivalent cation-containing compound may include, e.g., iron chloride (FeCl₃), iron nitrate (Fe(NO₃)₃), or iron sulfate (Fe₂(SO₄)₃).

In an implementation, the complex compound of iron ions may include, e.g., an iron trivalent cation-containing complex compound. The iron trivalent cation-containing complex compound may include a compound formed by reacting an iron trivalent cation with an organic or inorganic compound having functional group, e.g., a carboxylic acid, a phosphoric acid, a sulfuric acid, an amino acid, or an amine, in an aqueous solution. Examples of the organic or inorganic compound may include citrate, ammonium citrate, p-toluene sulfonic acid (pTSA), 1,3-propylenediaminetetraacetic acid (PDTA), ethylenediaminetetraacetic acid (EDTA), diethylenetriaminepentaacetic acid (DTPA), nitrilotriacetic acid (NTA), and ethylenediamine-N,N′-disuccinic acid (EDDS). Examples of the iron trivalent cation-containing compound may include ferric citrate, ferric ammonium citrate, Fe(III)-pTSA, Fe(III)-PDTA, and Fe(III)-EDTA.

In an implementation, the catalyst, e.g., the iron ion compound, the complex compound of iron ions, or the hydrate thereof, may be present in an amount of about 0.001 wt % to about 10 wt %, e.g., about 0.001 wt % to about 5 wt %, about 0.001 wt % to about 1 wt %, about 0.001 wt % to about 0.5 wt %, or about 0.002 wt % to about 0.1 wt %, based on the total weight of the CMP slurry composition. Within this range, it is more advantageous for the CMP slurry composition to improve the polishing rate of the tungsten metal layer.

(F) Organic Acid

The organic acid may help stabilize pH of the CMP slurry composition.

In an implementation, the organic acid may include a carboxylic acid, e.g., malonic acid, maleic acid, malic acid, or the like, or an amino acid, such as glycine, isoleucine, leucine, phenylalanine, methionine, threonine, tryptophan, valine, alanine, arginine, cysteine, glutamine, histidine, proline, serine, tyrosine, and lysine, or the like.

In an implementation, the organic acid may be present in an amount of about 0.001 wt % to about 10 wt %, e.g., about 0.002 wt % to about 5 wt %, about 0.005 wt % to about 1 wt %, or about 0.01 wt % to about 0.5 wt %, based on the total weight of the CMP slurry composition. Within this range, the organic acid may help stabilize pH of the CMP slurry composition.

In an implementation, the CMP slurry composition may have a pH of about 1 to about 6, e.g., about 1.5 to about 5, or about 2 to about 4. Within this range, the CMP slurry composition may facilitate oxidation of the tungsten pattern wafer to prevent reduction in polishing rate.

In an implementation, the CMP slurry composition may further include a pH regulator to help maintain a suitable pH value.

In an implementation, the pH regulator may include an inorganic acid, e.g., nitric acid, phosphoric acid, hydrochloric acid, or sulfuric acid, or an organic acid, e.g., an organic acid having a pKₐ of about 6 or less, e.g., acetic acid or phthalic acid. The pH regulator may include at least one base, e.g., an ammonia solution, sodium hydroxide, potassium hydroxide, ammonium hydroxide, sodium carbonate, or potassium carbonate.

In an implementation, the CMP slurry composition may further include a suitable additive, e.g., biocides, surfactants, dispersants, modifiers, surface activating agents, or the like. In the CMP slurry composition, the additives may be present in an amount of about 0.0001 wt % to about 5 wt %, e.g., about 0.0005 wt % to about 1 wt % or about 0.001 wt % to about 0.5 wt %. Within this range, the additives may realize effects thereof without adversely affecting the polishing rate.

In accordance with another embodiment, there is provided a method of polishing a tungsten pattern wafer. The polishing method may include polishing a tungsten pattern wafer using the CMP slurry composition.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Example 1

A CMP slurry composition was prepared by mixing 4.0 wt % of silica particles having an average particle size (D50) of about 95 nm as an abrasive agent, 0.004 wt % of a generation 1 poly(amidoamine) dendrimer (PAMAM dendrimer, ethylenediamine core, generation 1.0, Sigma Aldrich) as a dendritic poly(amidoamine) containing a terminal amino group, 0.01 wt % of iron nitrate nonahydrate as a catalyst, 0.04 wt % of malonic acid as an organic acid, 0.04 wt % of glycine, and the balance of deionized water as a solvent, based on the total weight of the CMP slurry composition. The CMP slurry composition was regulated to have a pH of 2.5 using a pH regulator. Then, 2 wt % of hydrogen peroxide was added as an oxidizing agent to the slurry composition immediately before polishing (or corrosion) evaluation of a tungsten pattern wafer.

### Example 2

A CMP slurry composition was prepared in the same manner as in Example 1 except that a generation 2 poly(amidoamine) dendrimer (PAMAM dendrimer, ethylenediamine core, generation 2.0, Sigma Aldrich) was used instead of the generation 1 poly(amidoamine) dendrimer.

### Example 3

A CMP slurry composition was prepared in the same manner as in Example 1 except that a generation 3 poly(amidoamine) dendrimer (PAMAM dendrimer, ethylenediamine core, generation 3.0, Sigma Aldrich) was used instead of the generation 1 poly(amidoamine) dendrimer.

### Example 4

A CMP slurry composition was prepared in the same manner as in Example 1 except that a generation 4 poly(amidoamine) dendrimer (PAMAM dendrimer, ethylenediamine core, generation 4.0, Sigma Aldrich) was used instead of the generation 1 poly(amidoamine) dendrimer.

### Example 5

A CMP slurry composition was prepared in the same manner as in Example 1 except that a generation 5 poly(amidoamine) dendrimer (PAMAM dendrimer, ethylenediamine core, generation 5.0, Sigma Aldrich) was used instead of the generation 1 poly(amidoamine) dendrimer.

### Comparative Example 1

A CMP slurry composition was prepared in the same manner as in Example 1 except that a generation 1 poly(amidoamine) dendrimer was not added.

### Comparative Example 2

A CMP slurry composition was prepared in the same manner as in Example 1 except that linear polyethyleneimine (average Mn: 2,500, Sigma Aldrich) was used instead of the generation 1 poly(amidoamine) dendrimer.

### Comparative Example 3

A CMP slurry composition was prepared in the same manner as in Example 1 except that branched polyethyleneimine (average Mn: 1,800, Sigma Aldrich) was used instead of the generation 1 poly(amidoamine) dendrimer.

### Comparative Example 4

A CMP slurry composition was prepared in the same manner as in Example 1 except that poly(diallyldimethylammonium chloride) (average Mw<100,000, Sigma Aldrich) was used instead of the generation 1 poly(amidoamine) dendrimer.

### Evaluation Example 1: Tungsten Corrosion Rate (Unit: Å/Min)

Evaluation of tungsten corrosion was carried out at 60° C. and tungsten corrosion rate was calculated based on electrical resistance corresponding to a difference in thickness before and after etching a tungsten blanket wafer (3 cm×3 cm) using a CMP slurry composition containing 2 wt % of hydrogen peroxide as an oxidizing agent.

### Evaluation Example 2: Polishing Evaluation

Polishing evaluation was carried out on the CMP slurry compositions under the following polishing conditions.

[Polishing Evaluation Condition]

(1) Polishing machine: Reflexion 300 mm (AMAT Co., Ltd.)

(2) Polishing condition
Polishing pad: IC1010/SubalV Stacked (Rodel Co., Ltd.)
Head speed: 101 rpm
Platen speed: 100 rpm
Pressure: 3.5 psi
Retainer Ring Pressure: 8 psi
Slurry flow rate: 250 ml/min
Polishing time: 30 sec

(3) Polishing target
Recess evaluation: A commercially available tungsten pattern wafer (MIT 854, 300 mm) was used.
Tungsten polishing rate evaluation: A blanket wafer was prepared by sequentially depositing titanium nitride (TiN) and tungsten to thicknesses of 300 Å and 6,000 Å, respectively, on a polycrystalline silicon substrate.

(4) Analysis method
Polishing rate of tungsten pattern wafer (unit: A/min): Polishing rate of the tungsten metal layer was calculated based on electrical resistance corresponding to difference in film thickness before and after polishing in evaluation under the above polishing conditions.
Recess (unit: nm): After polishing a wafer under the above polishing conditions, recess was evaluated by measuring a profile in a 0.3 μm×0.3 μm hole region in the wafer using an atomic force microscope (Uvx-Gen3, Bruker Co., Ltd.).

TABLE 1

| | Example | | | | | Comparative Example | | | |
|---|---|---|---|---|---|---|---|---|---|
| | 1 | 2 | 3 | 4 | 5 | 1 | 2 | 3 | 4 |
| Tungsten corrosion | 75 | 62 | 59 | 55 | 47 | 182 | 248 | 110 | 160 |
| rate (Å/min) | | | | | | | | | |
| Tungsten polishing | 3,211 | 3,458 | 3,324 | 3,148 | 3,110 | 4,987 | 2,675 | 2,811 | 3,385 |
| rate (Å/min) | | | | | | | | | |
| Recess (nm) | 10.5 | 7.9 | 8.8 | 10.3 | 9.3 | 32.1 | 18.2 | 16.1 | 19.4 |

From the above results, it may be seen that the CMP slurry compositions according to the Examples exhibited improved flatness of a tungsten pattern wafer while reducing the corrosion rate thereof.

Conversely, it may be seen that the composition free from the dendritic poly(amidoamine) (Comparative Example 1) exhibited an increase in tungsten corrosion rate and failed to improve recess characteristics; the composition containing linear polyethyleneimine instead of the dendritic poly(amidoamine) (Comparative Example 2) exhibited an increase in tungsten corrosion rate and a decrease in tungsten polishing rate; and the composition containing branched polyethyleneimine (Comparative Example 3) exhibited an increase in tungsten corrosion rate and a decrease in tungsten polishing rate. Further, it may be seen that the composition containing poly(diallyldimethylammonium chloride) instead of the dendritic poly(amidoamine) (Comparative Example 4) exhibited an increase in tungsten corrosion rate and a deterioration in recess characteristics.

One or more embodiments may provide a CMP slurry composition for polishing a tungsten pattern wafer, which may help improve flatness of the tungsten pattern wafer while reducing corrosion rate.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A CMP slurry composition for polishing a tungsten pattern wafer, the composition comprising:
a solvent;
an abrasive agent; and
a dendritic poly(amidoamine) containing a terminal amino group.

2. The CMP slurry composition as claimed in claim 1, wherein the dendritic poly(amidoamine) includes poly(amidoamine) dendrimers.

3. The CMP slurry composition as claimed in claim 1, wherein the dendritic poly(amidoamine) has a generation number of 1, 2, 3, 4, 5, 6, 7, 8, 9, or 10.

4. The CMP slurry composition as claimed in claim 1, wherein the dendritic poly(amidoamine) has a generation number of 1, 2, 3, 4, or 5.

5. The CMP slurry composition as claimed in claim 1, wherein the terminal amino group occupies about 10% to about 100% of total terminal groups of the dendritic poly(amidoamine).

6. The CMP slurry composition as claimed in claim 1, wherein the dendritic poly(amidoamine) is present in an amount of about 0.0001 wt % to about 0.1 wt %, based on a total weight of the CMP slurry composition.

7. The CMP slurry composition as claimed in claim 1, wherein the abrasive agent is present in an amount of about 0.001 wt % to about 20 wt %, based on a total weight of the CMP slurry composition.

8. The CMP slurry composition as claimed in claim 1, further comprising an oxidizing agent, a catalyst, or an organic acid.

9. The CMP slurry composition as claimed in claim 8, wherein:
the oxidizing agent is present in an amount of about 0.01 wt % to about 20 wt %,
the catalyst is present in an amount of about 0.001 wt % to about 10 wt %, and
the organic acid is present in an amount of about 0.001 wt % to about 10 wt %, based on a total weight of the CMP slurry composition.

10. The CMP slurry composition as claimed in claim 1, wherein the CMP slurry composition has a pH of about 1 to about 6.

11. A method of polishing a tungsten pattern wafer, the method comprising polishing a tungsten pattern wafer using the CMP slurry composition as claimed in claim 1.
